(19) United States
(12) Patent Application Publication
(10) Pub. No.: US 2005/0280442 A1
(43) Pub. Date: Dec. 22, 2005

(54) Semiconductor integrated circuit

(76) Inventor: Hiroyuki Shimbo, Osaka (JP)

Correspondence Address: MCDERMOTT WILL & EMERY LLP, 600 13TH STREET, N.W., WASHINGTON, DC, 20005-3096, US

(21) Appl. No.: 11/146,290

(22) Filed: Jun. 7, 2005

(30) Foreign Application Priority Data
Jun. 7, 2004 (JP) P2004-168258

(51) Int. Cl. H03K 19/094

(52) U.S. Cl. 326/86

(57) ABSTRACT

To obtain a delay circuit which does not involve an increase in a circuit area occupied by load transistors even when the number of inverters is increased, an integrated circuit device has four series-connected inverters 101 and two load transistors 104, 105, and is configured such that the A VDD source current to be consumed by all of the inverters 101 is supplied by way of the load transistor 104 and such that a VSS source current to be consumed by all of inverters 1010 is supplied by way of the other load transistor 105.

### BACKGROUND OF THE INVENTION

1. Field of the Invention

The present invention relates to a semiconductor integrated circuit, and more particularly, to a delay circuit intended for delaying transmission of a signal.

2. Description of the Related Art

In a semiconductor integrated circuit, a delay circuit is used for intentionally increasing a time required to transmit a signal.

For example, in a semiconductor integrated circuit designed by a synchronous design method of edge-trigger scheme, the delay circuit is used particularly in a pulse generation circuit provided in a pulse latch circuit.

FIG. 1 is a schematic diagram of the pulse latch circuit. Reference numeral 101 designates latch circuits of level trigger type; and 102 designate combination circuits.

A data signal output from the corresponding latch circuit 101 is input to the combination circuit 102, and a data signal output from the combination circuit 102 is input to the next latch circuit 101.

Reference numeral 103 designates a pulse generation circuit, and a clock signal 151 is input to the pulse generation circuit 103. A pulse signal 152 is output from the pulse generation circuit 103. The thus-output pulse signal 152 is input to the respective latch circuits 101, thereby triggering the respective latch circuits 101.

FIG. 2 shows a voltage waveform of the clock signal 151 and that of the pulse signal 152. Reference numeral 202 designates a voltage waveform of the clock signal 151 which is a square wave of given cycle. Reference numeral 203 designates a voltage waveform of the pulse signal 152, which is a square waveform having the same cycle as that of the clock signal 151. The square waveform 203 has a high voltage level only for a very short period of time 204 and a low voltage level in the remaining periods of time.

The pulse latch circuit uses a latch as a register of edge trigger type. Hence, at a point in time when output of data has been finished by triggering the latch, the pulse latch circuit must immediately retain an output from the latch. Therefore, the period 204 of the pulse wave form 152 is determined such that the latch circuit 101 remains open only for a period of time from when the latch circuit 101 has responded to an input until the output signal has finished changing.

FIG. 6 is a schematic diagram of the pulse generation circuit for generating the pulse signal 152 from the clock signal 151. Reference numeral 901 designates an input node, to which the clock signal 151 is input. Reference 902 designates a delay circuit having the function of outputting an input signal while delaying the phase thereof, and the clock signal 151 is input to the delay circuit 902. Reference numeral 903 designates a logic circuit, which performs logical operation for generating a pulse wave whose width corresponds to a phase difference between two input signals. Of the signals input to the logic circuit 903, one signal is the clock signal 151, and the other signal is a signal output from the delay circuit 902.

Reference numeral 904 designates an output node, which outputs a pulse signal 152.

At this time, the period of time 204 corresponds to a phase lag imparted by the delay circuit 902; that is, a transmission delay value from when a signal is input to the delay circuit 902 until the signal is output from the same circuit.

As mentioned above, the delay circuit is used in the pulse generation circuit provided in the pulse latch circuit.

A conventional example of the above-described delay circuit will be described hereunder.

FIG. 3 is a schematic diagram of the delay circuit described in claim 1 of JP-A-2-21910. Reference numeral 300 designates a first delay circuit. The first delay circuit 300 comprises four series-connected inverters 305, each inverter comprising Pch transistors 301, 302 and Nch transistors 303, 304. In each inverter 305, the drain of the Pch transistor 302 and that of the Nch transistor 303 are connected to an output terminal of the inverter 305. The gate potential of the Pch transistor 302 and that of the Nch transistor 303 are fixed. The source and drain of the Pch transistor 302 and those of the Nch transistor 303 are in conduction.

Moreover, the gate of the Pch transistor 301 and that of the Nch transistor 304 are connected to an input terminal of the respective inverter 305.

The Pch transistor 302 and the Nch transistor 303 act as load transistors that increase the delay of signal transmission in an inverter 305 of single stage. The reason for this is that the Pch transistor 302 and the Nch transistor 303 are fixed in conduction, and hence the amount of electric current flowing through the inverter can be reduced by means of provision of a resistive component between the source and drain of the respective transistors 302 and 303.

However, the inverter 305 provided in the first delay circuit 300 is characterized by comprising the Pch transistor 302 and the Nch transistor 303. A pair of load transistors is provided in each inverter, and hence the area of the load transistors included in the first delay circuit 300 increases in proportion to the number of inverters 305.

### SUMMARY OF THE INVENTION

In order to solve the problem, a semiconductor integrated circuit of the present invention comprises:

at least four series-connected inverting circuits; and

two load transistors, wherein

a VDD source current to be consumed by all the inverting circuits is supplied by way of one of the load transistors, and a VSS source current to be consumed by all the inverters is supplied by way of the other load transistor, and the inverting circuit has a function as the inverter which output the inverted signal.

In the above-described delay circuit, all of the inverting circuits are connected to a single load transistor. Hence, when compared with the first delay circuit 300 having the inverters which are equal in number to those of the delay circuit, the area occupied by the load transistors is reduced to one-quarter, and hence the area is diminished.

Moreover, the area of the load transistors included in the delay circuit does not increase even when the number of inverting circuits is increased. Hence, the area of load transistors in a delay circuit including inverting circuits arranged in four or more stages can be reduced at a ratio higher than that achieved in the second delay circuit 300.

The operating currents of all the inverting circuits are supplied by way of a single load transistor. Hence, the load transistor does not allow flow of an electric current which is greater in amount than the source-drain current of the transistor constituting the load transistor. Therefore, a total operating current achieved when the respective inverting circuits operate is limited by the source-drain current of the load transistor. Current drive capacity of respective output terminals of the plurality of inverting circuits which operate at the same time can be reduced. Therefore, the delay of signal transmission per inverting circuit stage can be increased. Therefore, the total number of inverting circuits included in the overall delay circuit can be diminished. Further, the area of the load transistors can be reduced greatly from that in the first delay circuit 300.

In view of the above description, the area of the load transistors can be reduced greatly from that in the case of the first delay circuit.

### BRIEF DESCRIPTION OF THE DRAWINGS

FIG. 1 is a schematic diagram of a pulse latch circuit;

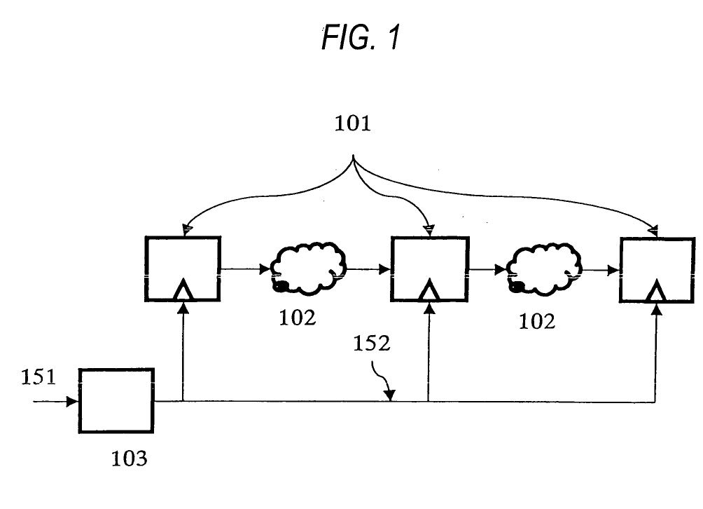

FIG. 2 is a voltage waveform of a clock signal 151 and that of a pulse signal 152;

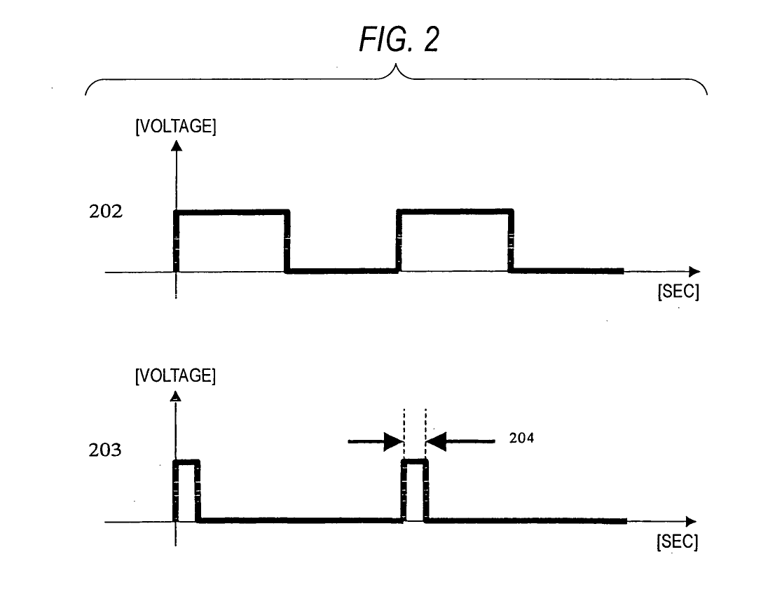

FIG. 3 is a schematic diagram of a delay circuit described in claim 1 of Patent Document 1;

FIG. 4 is a circuit diagram which is for describing a semiconductor integrated circuit of claim 1 according to the present invention and pertains to a delay circuit;

FIG. 5 is a circuit diagram which is for describing a semiconductor integrated circuit described in claims 7 and 8 and pertains to a pulse latch circuit;

FIG. 6 is a schematic diagram of a pulse generation circuit for generating the pulse signal 152 from the clock signal 151; and

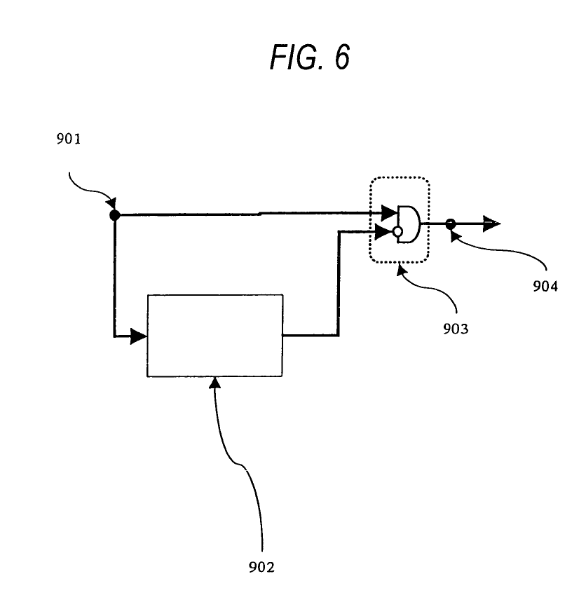

FIG. 7 is a circuit diagram which is for describing a semiconductor integrated circuit defined in claims 2 through 6 and pertains to the pulse generation circuit.

### DESCRIPTION OF THE PREFERRED EMBODIMENTS

An embodiment of the present invention will be described hereinbelow by reference to the drawings.

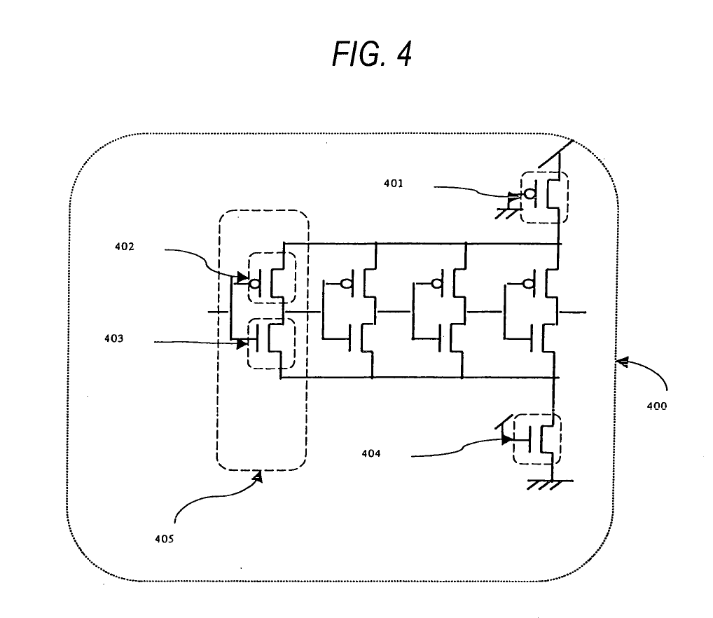

FIG. 4 is a circuit diagram which is for describing a semiconductor integrated circuit defined in claim 1 of the present invention and pertains to a delay circuit used in a pulse latch circuit. Reference numeral 400 designates a proposed delay circuit. The delay circuit 400 comprises four inverting circuits 405, and load transistors 401 and 404. Each inverter 405 comprises a Pch transistor 402 and an Nch transistor 403.

In each inverting circuit 405, the drain of the Pch transistor 402 and that of the Nch transistor 403 are connected to an output terminal of the inverting circuit 405, and the gates of the respective transistors 402, 403 are connected to an input terminal of the inverting circuit 405.

The load transistor 401 is formed from a Pch transistor, and the load transistor 404 is formed from an Nch transistor. The source of the load transistor 401 is connected to VDD, and the source of the load transistor 404 is connected to VSS. The gates of the load transistors 401, 404 are fixed such that the source-drains of the respective load transistors are brought into conduction.

The sources of the Pch transistors 402 included in all the inverters 405 are connected to the drain of the load transistor 401.

The sources of the Nch transistors 403 included in all the inverters 405 are connected to the drain of the load transistor 404.

The load transistors 401 and 404 are identical with the Pch transistor 302 and the Nch transistor 303 in terms of area and geometry. Similarly, the Pch transistor 402 and the Nch transistor 403 are identical with the Pch transistor 301 and the Nch transistor 304 in terms of area and geometry.

As mentioned above, all the inverters 405 in the proposed delay circuit 400 are connected to the same load transistors 401 and 404. Hence, when compared with the first delay circuit 300 having the same number of stages of inverters, the number of load transistors can be reduced to one-quarter without changing the total amount of impedance existing in the current channels of the respective inverters. Therefore, the area of the delay circuits can be reduced without changing the current drive capacity of the respective inverters and a signal transmission delay time.

The area of the load transistors included in the proposed delay circuit 400 does not increase with an increase in the number of inverting circuts. Hence, in the delay circuit including four or more stages of inverting circuits, the area of the load transistors can be reduced at a ratio higher than that achieved in the second delay circuit 300.

Moreover, the operating current of all the inverters is supplied after having passed through a single load transistor 401 or a single load transistor 404. The load transistor 401 or 404 cannot pass an electric current which is larger in amount than the source-drain current of the transistor constituting the load transistor.

For this reason, the total amount of operating current flowing when the respective inverters operate is limited by the source-drain current of the load transistor.

For example, when an H signal is input to the proposed delay circuit 400 shown in FIG. 4, the gate of the Nch transistor 403 of the inverting circuit 405 of the first stage is opened. As a result, the inverting circuit 405 of the first stage outputs an L signal formed by inversion of the input H signal, and the inverting circuit 405 of the second stage receives the L signal. At this time, the gate of the Pch transistor 402 provided in the inverting circuit 405 of the second stage is opened. As a result, the inverting circuit 405 of the second stage outputs an H signal formed by inversion of the input L signal. Similar signal transmission is repeated by the inverting circuits of the third and fourth stages.

In this case, the Nch transistors 403 provided in the respective inverting circuits 405 of the first and third stages receive an electric current which is to be consumed when the gates of the Nch transistors 403 are opened, by way of the common drain of the load transistor 404. However, the total amount of electric current supplied from the drain terminal of the load transistor 404 cannot exceed the source-drain current of the transistor constituting the load transistor 404. Therefore, the amount of electric current supplied to the sources of the respective Nch transistors is cut back under the influence of the amount of electric current supplied to the Nch transistors of other stages in addition to the source-drain current of the load transistor 404.

The amount of electric current supplied to the inverting circuit 405 of the first stage and the amount of electric current supplied to the inverter 405 of the third stage which operates at the same time as the inverter 405 of the first stage are influenced by each other and cut back.

As a result, the current drive capacity of the inverting circuit 405 of the first stage and that of the inverter 405 of the third stage are reduced when compared with that of the inverter 305 of the same stage described in connection with the first delay circuit 300, and, therefore, the signal transmission delay time per inverter stage is increased.

Similarly, the maximum total amount of electric current supplied to the Pch transistors 402 of the inverting circuits 405 of second and fourth stages is limited by the load transistor 404. Therefore, the current drive capacity of the inverting circuits 405 of second and fourth stages, which operate at the same time, is decreased when compared with that of the inverter 305. As a result, the signal transmission delay per inverter stage is increased.

As mentioned above, the proposed delay circuit 400 can lower the current drive capability of the respective output terminals of the plurality of inverters that are operating at the same time. Therefore, the total number of inverting circuits in the entire delay circuit can be reduced, and therefore the area of the load resistors can be reduced when compared with that in the first delay circuit 300.

The number of inverting circuits 405 is four or more, and inverting circuits 405 of any number are acceptable.

The number of Pch transistors 402 or Nch transistors 403 included in the inverting circuit 405 is not limited to one, but may be more than one. In such a case, the plurality of Pch transistors 402 or Nch transistors 403 are connected in series by way of the sources and drains of the transistors.

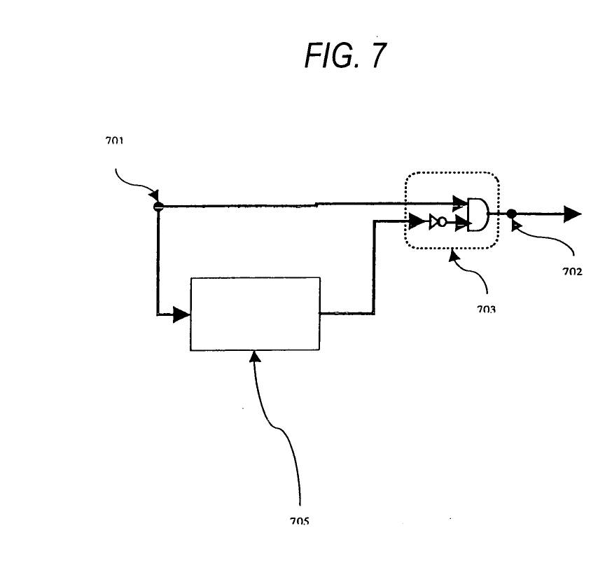

FIG. 7 is a circuit diagram of the pulse generation circuit for describing a semiconductor integrated circuit defined in claims 2 through 6 of the present invention. Reference numeral 701 designates an input node; 702 designates an output node; and 703 designates a logic circuit. The logic circuit 703 is formed from an inverter, and an AND circuit having two input terminals. A signal output from the inverter is input to one of the input terminals of the AND circuit. The signal input to the input node is input to the other input terminal of the AND circuit.

Reference numeral 705 designates a delay circuit for use in a pulse generation circuit, and the delay circuit 705 has the proposed delay circuit 400 shown in FIG. 4. The signal input to the input node is input to the inverting circuit 405 of first stage among the inverting circuits 403 shown in FIG. 4. The signal output from the inverting circuits of last stage among the inverting circuits 403 is input to the logic circuit 703, and further to the inverter of the logic circuit 703.

When the square wave is input to the input node 701, the output node 702 can output a pulse waveform whose potential level is changed by the amount equal to the time corresponding to the transmission delay induced when the waveform passes through the delay circuit 705.

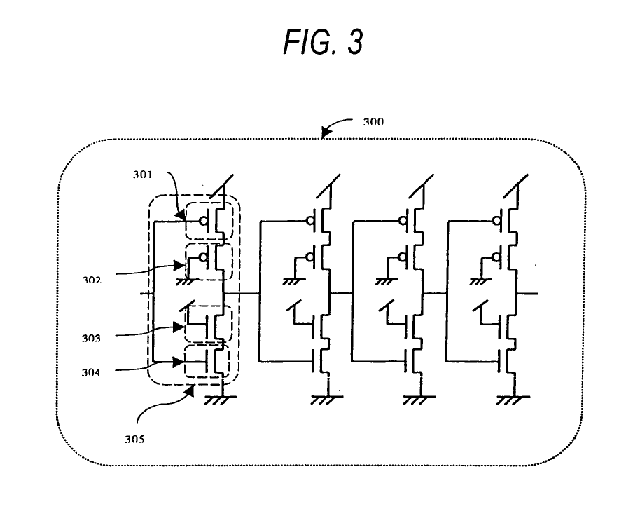

The circuit shown in FIG. 7 is provided with the proposed delay circuit 400 shown in FIG. 4. Hence, when compared with the circuit having the first delay circuit 300 shown in FIG. 3, the circuit can generate a pulse waveform while having a smaller area.

A NAND circuit may also be used in place of the AND circuit as the logic circuit shown in FIG. 7. Moreover, the inverter of the logic circuit shown in FIG. 7 may be omitted.

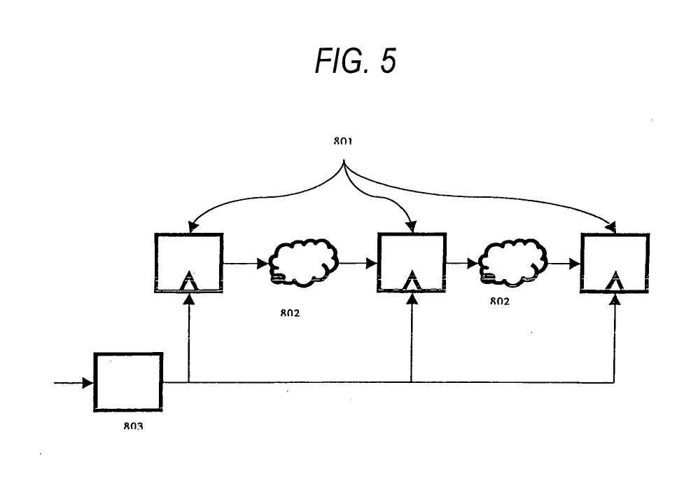

FIG. 5 is a circuit diagram which is for describing a semiconductor integrated circuit defined in claim 7 or 8 and which pertains to the pulse latch circuit.

Reference numeral 801 designates latch circuits. A pulse signal and a data signal are input to each of the latch circuits, and the latch circuit outputs a data signal in response to the edge of the pulse signal. Reference numeral 802 designates combination circuits. Each of the combination circuit receives the data signal from the corresponding latch circuit 801, performs arithmetic operation, and outputs the data signal to the next latch circuit 801. Reference numeral 803 designates a pulse generation circuit for pulse latching purpose, and the pulse generation circuit 803 has the pulse generation circuit shown in FIG. 7, receives a clock signal, and outputs a pulse signal. The thus-output pulse signal is transferred to each of the latch circuits 801, thereby triggering the latch circuit 801. Therefore, the entire pulse latch circuit acts as a synchronous circuit of edge trigger type.

Reference numeral 803 designates the pulse generation circuit shown in FIG. 7, and the pulse generation circuit 803 has the proposed delay circuit 400 shown in FIG. 4. Therefore, when compared with the circuit including the first delay circuit 300 shown in FIG. 3 in place of the delay circuit shown in FIG. 4, a synchronous circuit of edge trigger type can be embodied with a smaller area.

The pulse signal output from one pulse generation circuit may be connected to a single latch circuit.

Alternatively, a pulse signal output from one pulse generation circuit may be connected to a plurality of latch circuits.

The semiconductor integrated circuit of the present invention yields an effect of reducing the area of a delay circuit and is useful as a technique for curtailing the area of a chip during design of the layout of an integrated circuit.

1. A semiconductor integrated circuit comprising:
at least 4 inverting circuits each comprising a first power terminal,
a second power terminal, an input terminal, an output terminal;
first and second load transistors whose gate terminals are fixed to be conductive;
wherein the input terminal of one of the inverting circuit and the output terminal output terminal of another inverting circuit are connected respectively so that each of the inverting circuits are connected serially; and
the first power terminals of all of the inverting circuits are connected to the drain of the first load transistor; and the second power terminals of all of the inverting circuits is connected to the drain of the second load transistor.

2. A semiconductor integrated circuit comprising:
the semiconductor integrated circuit defined in claim 1; and
a logic circuit which receives, as an input, an input to the semiconductor integrated circuit and an output from the semiconductor integrated circuit.

3. The semiconductor integrated circuit according to claim 2, wherein the logic circuit is an NAND circuit, and the inverting circuits are provided in an odd number.

4. The semiconductor integrated circuit according to claim 2, wherein the logic circuit is an AND circuit, and the inverting circuits are provided in an odd number.

5. The semiconductor integrated circuit according to claim 2, wherein the logic circuit comprises inverter circuits for inverting an output from the semiconductor integrated circuit, and an NAND circuit for receiving, as an input, an input to the semiconductor circuit and an output from the inverter circuit; and wherein
the inverting circuits are provided in an even number.

6. The semiconductor integrated circuit according to claim 2, wherein the logic circuit comprises inverter circuits for inverting an output from the semiconductor integrated circuit, and an AND circuit for receiving, as an input, an input to the semiconductor circuit and an output from the inverter circuit; and wherein
the inverting circuits are provided in an even number.

7. A semiconductor integrated circuit comprising:
the semiconductor integrated circuit according to claim 6; and
at least one latch circuit which operates at an output timing of the semiconductor integrated circuit.

8. The semiconductor integrated circuit according to claim 7, wherein a clock signal is input to the semiconductor integrated circuit.
